(19) United States
(12) Patent Application Publication
(10) Pub. No.: US 2023/0107672 A1
(43) Pub. Date: Apr. 6, 2023

(54) DISPLAY PANEL AND METHOD FOR MANUFACTURING SAME

(71) Applicant: Shenzhen China Star Optoelectronics Semiconductor Display Technology Co., Ltd., Shenzhen, Guangdong (CN)

(72) Inventors: Zhiheng HUA, Shenzhen, Guangdong (CN); Bo YANG, Shenzhen, Guangdong (CN); Taijiun HWANG, Shenzhen, Guangdong (CN); Pengfei LIANG, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/048,632

(22) PCT Filed: Jun. 16, 2020
(86) PCT No.: PCT/CN2020/096305

§ 371 Date: Oct. 19, 2020

(30) Foreign Application Priority Data
Jun. 3, 2020 (CN) 202010495062.X

(51) Int. Cl. H01L 25/075; G09G 3/20; H01L 33/62

(52) U.S. Cl. CPC H01L 25/0753; G09G 3/2011; G09G 3/2014; H01L 33/62; G09G 3/32

(57) ABSTRACT

The present disclosure provides a display panel and a method for manufacturing the same, wherein the display panel includes a substrate and a plurality of display units disposed on the substrate, and the plurality of display units are disposed in an array; wherein each of the display units is integrated with micro light-emitting diode (LED) chips and pulse width modulation (PWM) chips electrically connected to the micro LED chips, and PWM circuits are formed in the PWM chip PWM driving circuits, and the PWM circuit the PWM driving circuits are configured to control light emitting time of the micro LED chips.

### FIELD OF INVENTION

The present disclosure relates to the field of display, and particularly relates to a display panel and a method for manufacturing the same.

### BACKGROUND OF INVENTION

An existing manufacturing method of micro light-emitting diode (micro LED) display panels are cutting LEDs into micro LEDs, and then transferring the micro LEDs to a display substrate in large quantities. Pixel driving circuits, etc., need to be made in advance on the display substrate. The pixel driving circuits, etc., occupy certain area of the display substrate and affect an aperture ratio of the display panels. Moreover, studies have shown that under different currents, light-emitting wavelengths of the micro LEDs present a U-shaped change. It causes problems such as a shift of an emission spectrum and uneven display of the panels. In addition, a manufacturing process of the driving circuits on a glass substrate is outdated, and is not conducive to mass production.

### Technical Problems

In view of this, the present disclosure aims at providing a display panel and a method for manufacturing the same that can increase the aperture ratio of the display panel, as well as solve the problems of the shift of the light emission spectrum of the micro LEDs and the uneven display of the panel.

### Technical Solutions

The present disclosure provides a display panel, wherein the display panel comprises a base plate and a plurality of display units disposed on the base plate, and the plurality of display units are disposed in an array; wherein, each of the display units is integrated with a micro LED chip and a pulse width modulation (PWM) chip electrically connected to the micro LED chip, a PWM circuit is formed in the PWM chip, and the PWM circuit is configured to control light emitting time of the micro LED chip.

In an embodiment, the micro LED chips and the PWM chips are stacked in a direction perpendicular to a display surface of the display panel.

In an embodiment, the PWM chips are bonded on the base plate, and the micro LED chips are disposed on sides of the PWM chips facing away from the base plate.

In an embodiment, each of the PWM chips is electrically connected to and controls one or more of the micro LED chips.

In an embodiment, a dimension of each of the PWM chips is tens of microns.

In an embodiment, the PWM chips are formed by an integrated circuit manufacturing process.

In an embodiment, the base plate is further provided with circuit elements and wires disposed thereon, the wires electrically connect the display units and the circuit elements, and the micro LED chips, the PWM chips, and the circuit elements together constitute a pixel driving circuits of the display panel.

In an embodiment, the pixel driving circuits comprises an input unit, a control unit coupled with the input unit, and a light emitting unit coupled with the control unit, and the input unit comprises a PWM circuit scan signal, a PWM circuit data signal, and a pulse amplitude modulation (PAM) circuit scan signal, and a PAM circuit data signal; the control unit comprises a PWM driving circuit electrically connected to the PWM circuit scan signal and the PWM circuit data signal, a first transistor electrically connected to the PWM driving circuit, and a second transistor electrically connected to the PAM circuit scan signal and the PAM circuit data signal; and the light emitting unit comprises the micro LED chips, a third transistor electrically connected to the micro LED chips, and a storage capacitor electrically connected to the third transistor.

In an embodiment, the display panel further comprises a packaging part for packaging the display units.

In an embodiment, the base plate is a glass base plate.

In an embodiment, the base plate is provided with a plurality of electrical contact pads disposed thereon, the plurality of contact pads correspond to the display units one-to-one, and each of the display units is bonded to a corresponding one of the electrical contact pads.

The present disclosure further provides a method for manufacturing a display panel, wherein the method comprises following steps: providing a first substrate, forming micro LED chips on the first substrate, providing a second substrate, and forming the PWM chips on the second substrate, wherein PWM circuits are formed in the PWM chips, and the PWM circuits are configured to control the light emitting time of the micro LED chips; transferring the micro LED chips to the second substrate and electrically connecting the micro LED chips to the PWM chips to form a plurality of display units; providing a base plate and bonding the plurality of display units on the base plate.

In an embodiment, manufacturing steps of the PWM chips comprise manufacturing large PWM driving circuits on the second substrate by an integrated circuit method, and then cutting the large PWM driving circuits to form micron-level PWM chips.

In an embodiment, a step of transferring the micro LED chips to the second substrate and electrically connecting with the PWM chips to form a plurality of display units further comprises a step of encapsulating the micro LED chips and the PWM chips to form a whole by using a packaging part.

### Beneficial Effects

Compared with the prior art, the display panel of the present disclosure adopts PWM driving circuits. The PWM driving circuits can reduce an influence of current density on light emission of the micro LED chips, reduce occurrences of color shift problems, and also compensate a TFT (thin film transistor) threshold voltage, thereby improving display uniformity. Compared with manufacturing driving circuits on a glass base plate, the method for manufacturing the display panel of the present disclosure uses an integrated circuit manufacturing process to form the PWM chips. The integrated circuit manufacturing process is more advanced and can reduce manufacturing difficulty. Only simple traces need to be made on the glass base plate to drive unit chips. Moreover, the glass base plate is easier to realize mass transfer of micro LEDs, compared with other base plates, which further reduces the manufacturing difficulty.

### DESCRIPTION OF DRAWINGS

In order to more clearly illustrate the technical solutions in the embodiments of the present disclosure, the drawings used in the description of the embodiments will be briefly described below. It is obvious that the drawings in the following description are only some embodiments of the present disclosure. Other drawings can also be obtained by those skilled in the art based on these drawings without making any creative effort.

FIG. 1 is a schematic structural view of a display panel according to a first embodiment of the present disclosure.

FIG. 2 is a schematic view of display units of the display panel according to the first embodiment of the present disclosure.

FIG. 3 is an equivalent circuit view of pixel driving circuits of the display panel according to the first embodiment of the present disclosure.

FIG. 4(a) to FIG. 4(c) are schematic views of steps of a method for manufacturing a display panel according to a second embodiment of the present disclosure.

### DETAILED DESCRIPTION OF EMBODIMENTS

The technical solutions in the embodiments of the present disclosure will be clearly and completely described with reference to accompanying drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts shall fall within protection scope of the present disclosure.

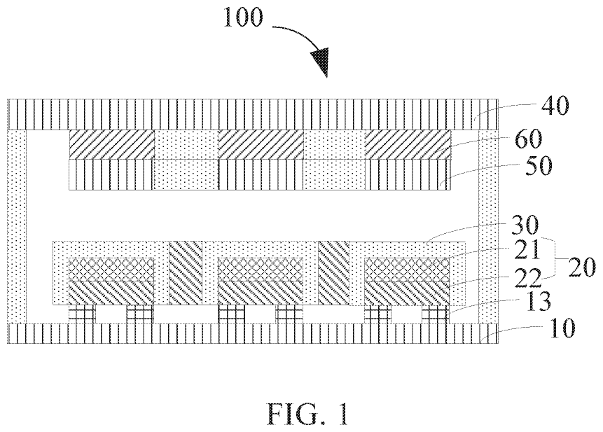

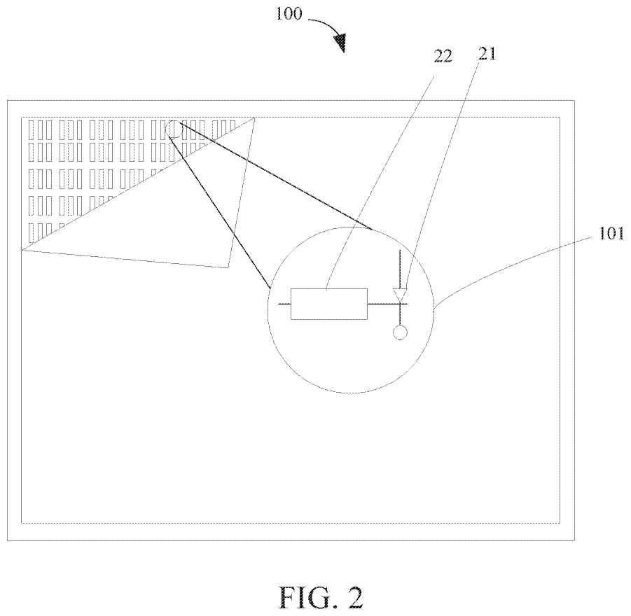

Referring to FIG. 1 and FIG. 2, a display panel 100 of a first embodiment of the present disclosure is a micro LED chip display panel. The display panel 100 includes a base plate 10 and a plurality of display units 20 disposed on the base plate 10. The base plate 10 may be a glass substrate. The plurality of display units 20 are disposed in an array and display images under control of a controller. Each of the display units 20 is integrated with a micro LED chip 21 and a PWM chip 22 connected to the micro LED chip 21. Wherein, the PWM chip 22 is formed with PWM circuit 22a. The PWM circuit 22a is configured to control the light emitting time of the micro LED chip. The PWM driving circuit 22a can use any PWM driving circuit structures in the prior art, which will not be repeated here.

In an embodiment, the micro LED chips 21 and the PWM chips 22 are stacked in a direction perpendicular to a display surface of the display panel 100. The PWM chips 22 and the micro LED chips 21 are integrated, and only occupy area of one of the PWM chips 22 and the micro LED chips 21 (depending on dimensions of the PWM chips 22 and the micro LED chips 21). In an embodiment, the PWM chips 22 are disposed between the micro LED chips 21 and the base plate 10 so that light can be emitted. Specifically, the PWM chips 22 are bonded on the base plate 10. The micro LED chips 21 are disposed at sides of the PWM chips 22 away from the base plate 10. It can be understood that, in another embodiment, the micro LED chips 21 and the PWM chips 22 can also be disposed horizontally on the display surface of the display panel 100.

In each of the display units 20, each of the PWM chips 22 is electrically connected to one or more of the micro LED chips 21 and controls light emitting of one or more of the micro LED chips 21. The micro LED chips 21 may be blue micro LED chips, green micro LED chips, or red micro LED chips, and so on. The PWM chips 22 has contact pins connected to the micro LED chips 21, and a number of the contact pins depends on a number of the connected micro LED chips 21.

If PWM circuits in the prior art are directly formed on the substrate, its manufacturing accuracy can only reach the micron level. In this present disclosure, the PWM circuits are made into the PWM chips 22 by the method of manufacturing an integrated circuit, which can achieve nanometer-level manufacturing accuracy. Specifically, the manufacturing accuracy of several hundred nanometers can be achieved, and sizes of the PWM chips 22 can be controlled to tens of micrometers, such as about 20 micrometers.

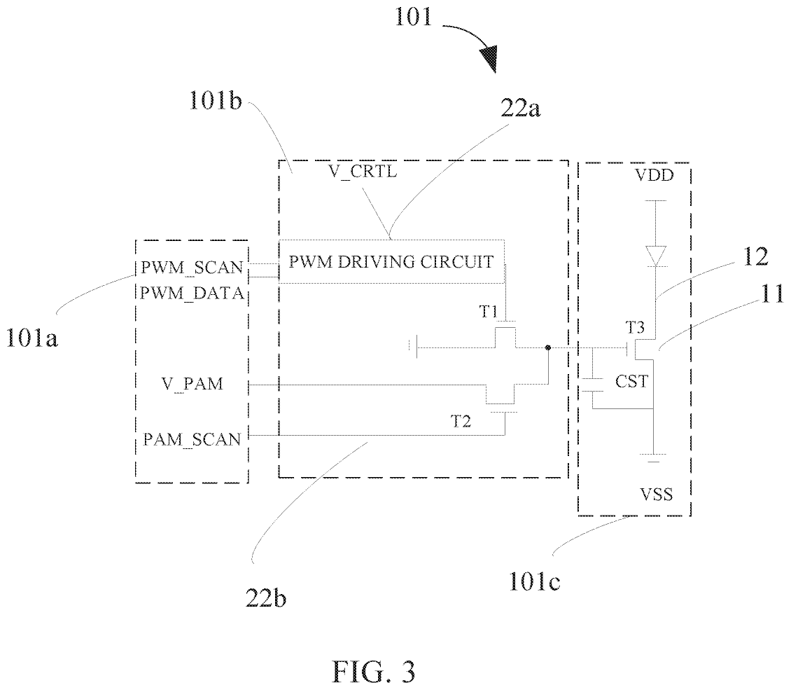

Referring to FIG. 2 and FIG. 3, the base plate 10 is further provided with circuit elements 11 and wires 12, and the wires 12 electrically connect the display units 20 and the circuit elements 11. The micro LED chips 21, the PWM chips 22, and the circuit elements 11 together constitute the pixel driving circuits 101 of the display panel 100. The circuit element 12 specifically includes a transistor, a capacitor, and so on. In addition, a plurality of contact pads 13 are disposed on the base plate 10. Multiple of the electrical contact pads 13 correspond to the display units 20 one-to-one. Each of the display units 20 is bonded to the corresponding electrical contact pads 13.

The pixel driving circuit 101 includes an input unit 101a, a control unit 101b coupled with the input unit 101a, and a light-emitting unit 101c coupled with the control unit 101b. The control unit 101b is configured to drive the light-emitting unit 101c to emit light.

Specifically, the input unit 101a is configured to detect light chromaticity information of the light-emitting unit 101c and transmit the light chromaticity information to the control unit 101b. Wherein the input unit 101a includes a PWM circuit scan signal (PWM_SCAN), a PWM circuit data signal (PWM_DATA), a PAM circuit scan signal (PAM_SCAN), and a PAM circuit data signal (V_PAM).

Specifically, the control unit 101b includes a PWM driving circuit 22a electrically connected to the PWM circuit scan signal (PWM_SCAN) and the PWM circuit data signal (PWM_DATA), a first transistor T1 electrically connected to the PWM driving circuit 22a, and a second transistor T2 electrically connected to the PAM circuit data signal (V_PAM) and the PAM circuit scan signal (PAM_SCAN). The PWM circuit scan signal (PWM_SCAN) is connected to a gate of the first transistor T1 through the PWM driving circuit 22a, and is configured to scan a PWM control unit line by line; and the PWM circuit data signal (PWM_DATA) is connected to the gate of the first transistor T1 through the PWM driving circuits 22a, and is configured to control the light-emitting time of the light-emitting unit. A source of the first transistor T1 is grounded, which is equivalent to being electrically connected to a reset signal Vi; the PAM circuit scan signal (PAM_SCAN) is connected to a gate of the second transistor T2 for progressive scan of the PAM control unit; the PAM circuit data signal (V_PAM) is connected to a source of the second transistor T2 and used to control a driving current in the light-emitting unit; and specifically, a voltage of the PAM circuit data signal (V_PAM) is a fixed reference voltage (VREF).

The light-emitting unit 30 includes the micro LED chip 21, a third transistor T3 electrically connected to the micro LED chip 21, and a storage capacitor CST electrically connected between a gate and a drain of the third transistor T₃.

The specific working process of the display panel 100 is as follows.

The PAM circuit scan signal (PAM_SCAN) scans line by line and is written into the PAM circuit data signal (PAM_DATA). The PAM circuit data signal (V_PAM) can be provided by a fixed reference voltage (VREF); after that, the PWM circuit scan signal (PWM_SCAN) scans row by row, and is written into the PWM circuit data signal (PWM_DATA), the PWM circuit data signal (PWM_DATA) determines the light-emitting time of the light-emitting unit 101c; after that, the PWM circuit data signal (PWM_DATA) is output to the PWM circuit 20a, the PWM circuits 20a convert the different PWM circuit data signals (PWM_DATA) into the light emission control time of the light-emitting units 101c, finally release the charge in the storage capacitors, and the conversion of the input voltage to the light-emitting time of the light-emitting unit 101c is completed.

In this present disclosure, by inputting the same control voltage V_CTRL to the PWM driving circuits, the thin film transistors (TFTs) are controlled to generate same currents, and at the same time, the light emitting time of the micro LED chips is controlled to emit light of different brightness. In the existing pixel driving circuits, pixel voltages are controlled by a simple PAM voltage, but the PAM voltage is fixed and uniform, so currents of the micro LED chips are the same, which cannot solve problems of the spectral shift and uneven display. Meanwhile, the PWM driving circuits control the light emitting time of the micro LED chips, which can make the micro LED chips emit light of different brightness. The PWM driving circuits can reduce the influence of current density on light emission of micro LEDs, reduce the occurrence of the color shift problem, and also compensate the TFT threshold voltage to improve display uniformity.

In addition, the display panel 100 further includes packaging parts 30 for packaging the display units 20. Each of the packaging parts 30 can encapsulate one of display units 20 or multiple display units 20. The package parts 30 are wrapped around the micro LED chips 21 and the PWM chips 22, and encapsulate the micro LED chips 21 and the PWM chips 22 as a whole.

The display panel 100 further includes a second base plate 40 disposed opposite to the first base plate 10. A color conversion layer 50 and a filter layer 60 disposed opposite to the display units 20 are further disposed between the first base plate 10 and the second base plate 40. The color conversion layer 50 and the filter layer 60 are configured to convert and purify the light emitted by the blue micro LED chips. In other embodiments of the present disclosure, if micro LED chips with three colors of red, green, and blue are configured to display, the color conversion layer 50 does not need to be provided.

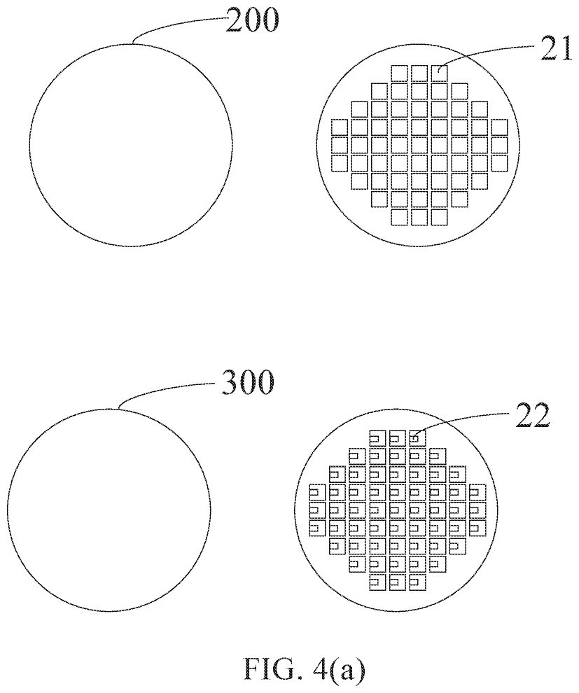

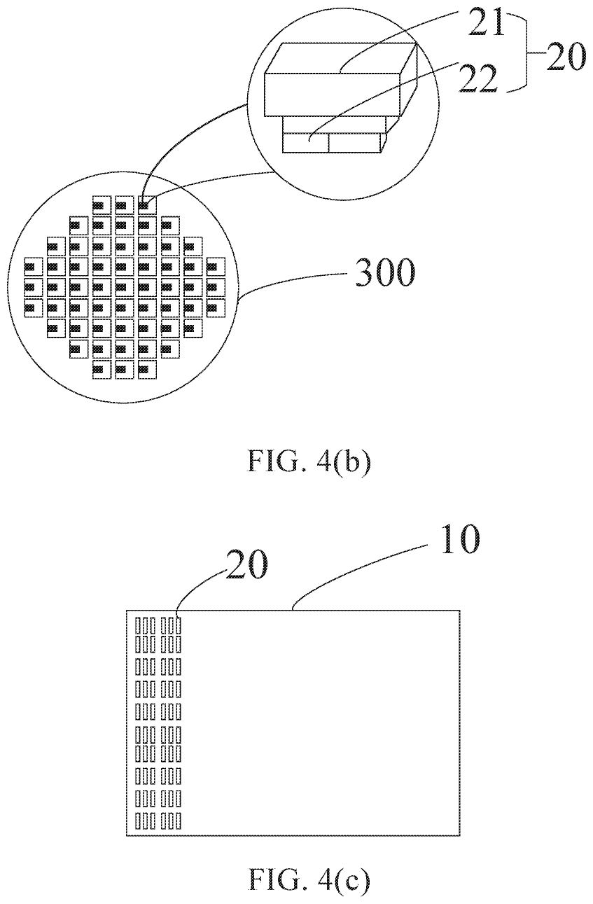

Referring to FIG. 4(a) to FIG. 4(c), a second embodiment of the present disclosure provides a method for manufacturing a display panel, which includes the following steps.

S1: a first substrate 200 is provided, and micro LED chips 21 are formed on the first substrate 200. A second substrate 300 is provided, and the PWM chips 22 are formed on the second substrate 300. PWM circuits 22a are formed in the PWM chips 22. The PWM circuits 22a are configured to control the light emitting time of the micro LED chips 21.

The step of forming the micro LED chips 21 on the first substrate 200 and forming the PWM chips 22 on the second substrate 300 are performed independently.

The step for manufacturing the micro LED chips 21 includes: epitaxially manufacturing LED chips on the first substrate 200, and then cutting the manufactured LED chips into micro LED chips 21 of micron size. The first substrate 200 is a sapphire substrate. The micro LED chips 21 may be blue micro LED chips, green micro LED chips, or red micro LED chips, and so on.

In this embodiment, all the micro LED chips 21 are blue micro LED chips.

The PWM chips 22 include the PWM driving circuits 22a. The PWM driving circuits 22a can use any the PWM driving circuit structure in the prior art. The step for manufacturing the PWM chips 22 include fabricating a large piece of PWM driving circuits on the second substrate 300 by an integrated circuit method, and then cutting the large piece of PWM driving circuits to form micron-level PWM chips 22. The second substrate 300 is a wafer.

The PWM driving circuits in the present disclosure are manufactured by an integrated circuit process. The integrated circuit process is more advanced than the process for manufacturing pixel driving circuits on a glass substrate in the prior art, and can achieve nanometer-level manufacturing accuracy. Specifically, the manufacturing accuracy of several hundred nanometers can be achieved, and the PWM chips 22 can be controlled to a dimension of micrometers, for example, about 20 micrometers. Thus, it is beneficial to mass production of display panels.

S2: the micro LED chips 21 are transferred to the second substrate 300 and are electrically connected with the PWM chips 22 to form a plurality of display units 30.

In each of the display units 20, each of the PWM chips 22 can be electrically connected to one or more micro LED chips 21 and control the light emission of one or more micro LED chips 21. In this step, it may further include a step of encapsulating the micro LED chips 21 and the PWM chips 22 as a whole by using the packaging parts 30 (referring to FIG. 1).

S3: a first base plate 10 is provided, and a plurality of display units 20 are bonded on the first base plate 10. In this step, the display units 20 formed on the second substrate 300 are sorted and binned, and the display units 20 are transferred and bonded on the first base plate 10.

In an embodiment, the display units 20 are bonded to the first base plate 10 in a manner that the micro LED chips 21 and the PWM chips 22 are stacked in a direction perpendicular to the display surface of the display panel 100. In an embodiment, the PWM chips 22 are disposed between the micro LED chips 21 and the base plate 10 so that light can be emitted. Specifically, the PWM chips 22 are bonded on the base plate 10. The micro LED chips 21 are disposed at the sides of the PWM chips 21 facing away from the base plate 10. In another embodiment, the micro LED chips 21 and the PWM chips 22 can further be disposed horizontally on the display surface of the display panel 100.

The first base plate 10 is a glass substrate. Compared with other substrates, the glass substrate is easier to realize the mass transfer of the display units 20. Please also refer to FIG. 2, which is an enlarged view of the display units of the display panel 100.

The base plate 10 is further provided with circuit elements 11 and wirings 12 electrically connecting the display units 20 and the circuit elements 11. The micro LED chips 21, the PWM chips 22, and the circuit elements 11 together constitute the pixel driving circuits 101 of the display panel 100. The circuit element 12 includes transistors and capacitors. In addition, a plurality of electrical contact pads 13 are provided on the base plate 10. The multiple electrical contact pads 13 correspond to the display units 20 one-to-one. Each of the display units 20 is bonded to the corresponding one of the electrical contact pads 13.

The structure of the pixel driving circuits 101 is described in the first embodiment, and will not be repeated here.

In addition to the above steps, the method for manufacturing the display panel may further includes the step of fabricating the color conversion layer and the filter layer on the second base plate, and the step of aligning and attaching the first base plate and the second base plate to form the display panel.

The micro LED chip display panel with a PWM driving function can be manufactured by the above manufacturing method.

Compared with the prior art, the display panel of the present disclosure uses a PWM driving circuit. The PWM driving circuit can reduce the influence of current density on the light emission of the micro LED chips, reduce the occurrence of the color shift problem, and also compensate the TFT threshold voltage to improve display uniformity. Compared with manufacturing driving circuits on a glass substrate, the method for manufacturing the display panel of the present disclosure uses an integrated circuit manufacturing process to form the PWM chips. The integrated circuit manufacturing process is more advanced and can reduce the manufacturing difficulty. Only simple wires need to be made on the glass substrate to drive the display units. Moreover, the glass substrate is easier to realize the mass transfer of micro LEDs, compared with other substrates, which further reduces the manufacturing difficulty.

The liquid crystal display components provided by the embodiments of the present disclosure have been described in detail above, and specific examples are configured to describe the principles and implementation manners of the present disclosure. The descriptions of the above embodiments are only configured to help understand the present disclosure. At the same time, for those skilled in the art, according to the idea of the disclosure, there will be changes in the specific implementation and the scope of disclosure. In summary, the content of this specification should not be construed as a limitation to the present disclosure.

1. A display panel, wherein the display panel comprises a substrate and a plurality of display units disposed on the substrate, and the plurality of display units are disposed in an array; wherein,
each of the display units is integrated with micro light-emitting diode (LED) chips and pulse width modulation (PWM) chips electrically connected to the micro LED chips, the PWM driving circuits are formed in the PWM chips, and the PWM driving circuits are configured to control light emitting time of the micro LED chips.

2. The display panel in claim 1, wherein the micro LED chips and the PWM chips are stacked in a direction perpendicular to a display surface of the display panel.

3. The display panel in claim 2, wherein the PWM chips are bonded on the base plate, and the micro LED chips are disposed on sides of the PWM chips facing away from the base plate.

4. The display panel in claim 1, wherein each of the PWM chips is electrically connected to and controls one or more of the micro LED chips.

5. The display panel in claim 1, wherein a dimension of each of the PWM chips is tens of microns.

6. The display panel in claim 1, wherein the PWM chips are formed by an integrated circuit manufacturing process.

7. The display panel in claim 1, wherein the base plate is further provided with circuit elements and wires disposed thereon, the wires electrically connect the display units and the circuit elements, and the micro LED chips, the PWM chips, and the circuit elements together constitute a pixel driving circuits of the display panel.

8. The display panel in claim 7, wherein the pixel driving circuits comprises an input unit, a control unit coupled with the input unit, and a light emitting unit coupled with the control unit, and the input unit comprises a PWM circuit scan signal, a PWM circuit data signal, and a pulse amplitude modulation (PAM) circuit scan signal, and a PAM circuit data signal;
the control unit comprises a PWM driving circuit electrically connected to the PWM circuit scan signal and the PWM circuit data signal, a first transistor electrically connected to the PWM driving circuit, and a second transistor electrically connected to the PAM circuit scan signal and the PAM circuit data signal; and
the light emitting unit comprises the micro LED chips, a third transistor electrically connected to the micro LED chips, and a storage capacitor electrically connected to the third transistor.

9. The display panel in claim 1, wherein the display panel further comprises a packaging part for packaging the display units.

10. The display panel in claim 1, wherein the base plate is a glass base plate.

11. The display panel in claim 1, wherein the substrate is provided with a plurality of electrical contact pads disposed thereon, the plurality of electrical contact pads correspond to the display units one-to-one, and each of the display units is bonded to a corresponding one of the electrical contact pads.

12. A method for manufacturing a display panel, wherein the method comprises following steps:
providing a first base plate, forming micro LED chips on the first base plate, providing a second substrate, and forming the PWM chips on the second substrate, wherein PWM driving circuits are formed in the PWM chips, and the PWM driving circuits are configured to control the light emitting time of the micro LED chips;
transferring the micro LED chips to the second substrate and electrically connecting the micro LED chips to the PWM chips to form a plurality of display units;
providing a base plate and bonding the plurality of display units on the base plate.

13. The method for manufacturing the display panel in claim 12, wherein the micro LED chips and the PWM chips are stacked in a direction perpendicular to a display surface of the display panel.

14. The method for manufacturing the display panel in claim 12, wherein the PWM chips are bound on the base plate, and the micro LED chips are disposed on a side of the PWM chips facing away from the base plate.

15. The method for manufacturing the display panel in claim 12, wherein each of the PWM chips is electrically connected to the micro LED chips, and controls the light emission of one or more of the micro LED chips.

16. The method for manufacturing the display panel in claim 12, wherein a dimension of each of the PWM chips is tens of microns.

17. The method for manufacturing the display panel in claim 12, wherein manufacturing steps of the PWM chips comprise manufacturing large the PWM driving circuits on the second substrate by an integrated circuit method, and then cutting the large PWM driving circuits to form micron-level PWM chips.

18. The method for manufacturing the display panel in claim 12, wherein the base plate is further provided with circuit elements and wires disposed thereon, the wires electrically connect the display units and the circuit elements, and the micro LED chips, the PWM chips, and the circuit elements together constitute a pixel driving circuits of the display panel.

19. The method for manufacturing the display panel in claim 12, wherein the pixel driving circuits comprises an input unit, a control unit coupled with the input unit, and a light emitting unit coupled with the control unit, and the input unit comprises a PWM circuit scan signal, a PWM circuit data signal, and a PAM circuit scan signal, and a PAM circuit data signal;
the control unit comprises a PWM driving circuit electrically connected to the PWM circuit scan signal and the, PWM circuit data signal, a first transistor electrically connected to the PWM driving circuit, and a second transistor electrically connected to the PAM circuit scan signal and the PAM circuit data signal; and
the light emitting unit comprises the micro LED chips, a third transistor electrically connected to the micro LED chips, and a storage capacitor electrically connected to the third transistor.

20. The method for manufacturing the display panel in claim 12, wherein a step of transferring the micro LED chips to the second substrate and electrically connecting with the PWM chips to form a plurality of display units further comprises a step of encapsulating the micro LED chips and the PWM chips to form a whole by using a packaging part.
